(19) United States
(12) Patent Application Publication
(10) Pub. No.: US 2015/0155513 A1
(43) Pub. Date: Jun. 4, 2015

(54) ORGANIC LIGHT EMITTING DEVICE AND ORGANIC LIGHT EMITTING DISPLAY DEVICE USING THE SAME

(71) Applicant: LG DISPLAY CO., LTD., Seoul (KR)

(72) Inventors: Sung-Hoon Pieh, Seoul (KR); Chang-Wook Han, Seoul (KR); Seok-Joon Oh, Gyeonggi-do (KR); Ki-Woog Song, Gyeonggi-do (KR); Tae-Shick Kim, Gyeonggi-do (KR); Hee-Dong Choi, Gyeonggi-do (KR); Seung-Hyun Kim, Gwangju (KR); Seong-Su Jeon, Gyeonggi-do (KR); Chi-Yul Song, Seoul (KR)

(73) Assignee: LG DISPLAY CO., LTD., Seoul (KR)

(21) Appl. No.: 14/557,720

(22) Filed: Dec. 2, 2014

(30) Foreign Application Priority Data
Dec. 3, 2013 (KR) 10-2013-0149330

(51) Int. Cl. H01L 51/50; H01L 51/00; H01L 27/32

(52) U.S. Cl. CPC H01L 51/504; H01L 51/5072; H01L 51/5056; H01L 51/5016; H01L 27/3209; H01L 51/0055; H01L 51/0072; H01L 51/0059

(57) ABSTRACT

An organic light emitting device containing a multilayer stack structure including n stacks between an anode and a cathode is described, wherein the respective stacks comprise a hole transport layer, a light emitting layer and an electron transport layer, an n-type charge generation layer and a p-type charge generation layer respectively provided between the different adjacent stacks, wherein the p-type charge generation layer comprises an indenofluorenedione derivative represented by Formula 1 or an imine derivative represented by Formula 2 or 3.

This application claims the benefit of Korean Patent Application No. 10-2013-0149330, filed on Dec. 3, 2013, which is hereby incorporated by reference as if fully set forth herein.

### BACKGROUND OF THE INVENTION

1. Field of the Invention

The present application relates to an organic light emitting device comprising a multilayer stack structure to simplify the configuration of the layers and reduce driving voltage and an organic light emitting display device using the same.

2. Discussion of the Related Art

In recent years, the coming of the information age has brought about rapid development in displays which visually express electrical information signals. In response, a variety of flat display devices having superior properties such as slimness, light weight and low power consumption are being developed and are actively used as alternatives to conventional cathode ray tubes (CRTs).

Specifically, examples of the flat display devices include liquid crystal display (LCD) devices, plasma display panel (PDP) devices, field emission display (FED) devices, organic light emitting display (OLED) devices and the like.

Of these, organic light emitting display devices are considered to be competitive applications which require no additional light sources, are compact and render clear color.

Formation of an organic light emitting layer is required for such an organic light emitting display device.

Organic light emitting display devices which emit white light by laminating a stack structure which includes different colors of organic light emitting layers, instead of patterning the organic light emitting layer on a pixel basis, are suggested.

That is, the organic light emitting display device is produced by depositing respective layers between an anode and a cathode without using a mask in the formation of light emitting diodes. Organic films that include an organic light emitting layer are formed by depositing different components for the films under vacuum.

The organic light emitting display device may be utilized in a variety of applications including slim light sources, backlights of liquid crystal display devices or full-color display devices using color filters.

Meanwhile, conventional organic light emitting display devices include a plurality of stacks emitting different colors of light wherein each of the stacks includes a hole transport layer, a light emitting layer and an electron transport layer. In addition, each light emitting layer includes a single host and a dopant for rendering color of emitted light, to emit the corresponding color of light based on recombination of electrons and holes injected into the light emitting layer. In addition, a plurality of stacks, each including different colors of light emitting layers, is formed by lamination. In this case, a charge generation layer (CGL) is formed between the stacks so that electrons received from the adjacent stack or holes are transported thereto. In addition, the charge generation layer is divided into an n-type charge generation layer and a p-type charge generation layer. A conventional charge generation layer structure capable of improving both driving voltage and lifespan is not reported.

The conventional organic light emitting display device has the following problems.

An n-type charge generation layer and a p-type charge generation layer are separately formed as the charge generation layer for connecting adjacent stacks to each other. In addition, the n-type charge generation layer is formed using an electron-transporting organic substance and an alkali metal as a dopant and the p-type charge generation layer is formed using a hole-transporting organic substance and a p-type dopant such as F4-TCNQ.

In recent years, a method of forming a p-type charge generation layer as a single layer and forming a hole transport layer as a single layer by changing the material for the p-type charge generation layer to a material capable of further efficiently receiving electrons, such as HAT-CN, are suggested. In this case, performance is improved, but problems of increased driving voltage and decreased lifespan are generated. For this reason, change to such a material only in consideration of improved performance is unsuitable.

### SUMMARY OF THE INVENTION

Accordingly, the present application is directed to an organic light emitting device and an organic light emitting display device that substantially obviate one or more problems due to limitations and disadvantages of the related art.

An object of the present invention is to provide an organic light emitting device comprising a multilayer stack structure to simplify the configuration of the layers and reduce driving voltage. Another object is an organic light emitting display device using the organic light emitting device.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structures particularly pointed out in the written description and claims hereof as well as the appended drawings.

To achieve these objects and other advantages and in accordance with the purpose of the invention, as embodied and broadly described herein, an organic light emitting device includes n (wherein n is a natural number of 2 or more) stacks between an anode and a cathode, wherein the respective stacks include a hole transport layer, a light emitting layer and an electron transport layer, an n-type charge generation layer and a p-type charge generation layer respectively provided between the different adjacent stacks, wherein the p-type charge generation layer includes an indenofluorenedione derivative represented by Formula 1 or an imine derivative represented by Formula 2 or 3:

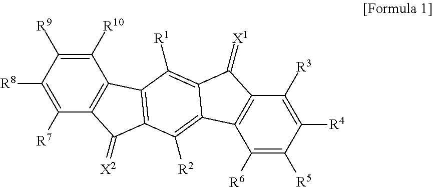

wherein X¹ and X² each independently represents any one of Formulae (I) to (V), R¹ to R¹⁰ each independently represents a hydrogen atom, an alkyl group, an aryl group, a heterocycle, a halogen atom, a fluoroalkyl group, an alkoxy group, an aryloxy group or a cyano group, and R³ to R⁶ are bonded to each other to form a ring or R⁷ to R¹⁰ are bonded to each other to form a ring,

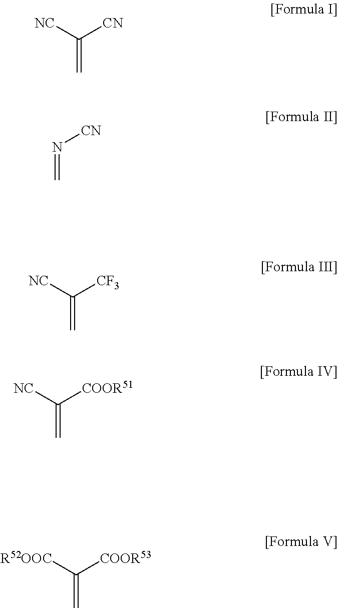

wherein R⁵¹ to R⁵³ each independently represents a hydrogen atom, a fluoroalkyl group, an alkyl group, an aryl group or a heterocycle, and R⁵² and R⁵³ are bonded to each other to form a ring,

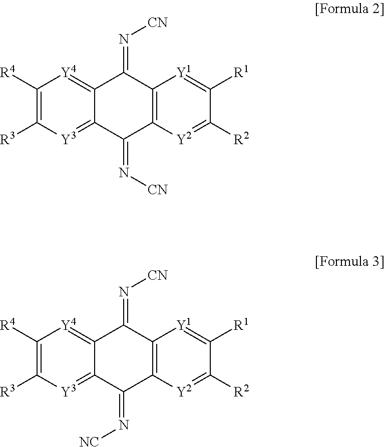

wherein Y¹ to Y⁴ each independently represents a carbon or nitrogen atom, R¹ to R⁴ each independently represents a hydrogen atom, an alkyl group, an aryl group, a heterocycle, a halogen atom, a fluoroalkyl group or a cyano group, and R¹ and R², or R³ and R⁴ are bonded together to form a ring.

The p-type charge generation layer may include the indenofluorenedione derivative of Formula 1 or the imine derivative of Formula 2 or 3 as a host and may include a component of the hole transport layer most adjacent to the p-type charge generation layer as a dopant.

The component of the hole transport layer may be present in an amount of 0.5% to 10% in the p-type charge generation layer.

The hole transport layer most adjacent to the p-type charge generation layer may have a thickness of 50 Å to 200 Å.

The thickness of the hole transport layer most adjacent to the p-type charge generation layer may be 50 Å to 700 Å.

The hole transport layer most adjacent to the p-type charge generation layer may have a triplet level of 2.5 eV or more.

In addition, a HOMO level of the hole transport layer most adjacent to the p-type charge generation layer may be lower than or equal to a value which is obtained by adding 0.3 eV to a LUMO level of a host of the adjacent p-type charge generation layer.

The n stacks present between the anode and the cathode may include three stacks, a light emitting layer of a first stack adjacent to the anode and a light emitting layer of a third stack adjacent to the cathode may be blue light emitting layers, and a light emitting layer of a second stack may be a phosphorescent emitting layer and emit yellow green or yellowish green light, or red green light.

In addition, the phosphorescent emitting layer of the second stack may include a host of at least one hole transport material and a host of at least one electron transport material.

The n-type charge generation layer may include an electron-transporting organic substance and an n-type organic dopant. Alternatively, the n-type charge generation layer may include an electron-transporting organic substance and a metal selected from an alkali metal group and an alkaline earth metal group, as a dopant.

The electron-transporting organic substance constituting the n-type charge generation layer may be a fused aromatic ring including a heterocyclic ring.

The dopant may be present in an amount of 0.4% to 3% in the n-type charge generation layer.

The n-type charge generation layer may have a thickness of 50 Å to 250 Å.

A triplet level of the hole transport layer and the electron transport layer adjacent to the light emitting layer of each stack may be 0.01 eV to 0.4 eV higher than a triplet level of a host of the light emitting layer.

In another aspect of the present application, an organic light emitting display device includes a substrate having a plurality of pixels defined in the form of a matrix, the substrate including a thin film transistor disposed in each of the pixels, a first electrode connected to the thin film transistor, n (wherein n is a natural number of 2 or more) stacks disposed on the first electrode, the stacks, each including a hole transport layer, a light emitting layer and an electron transport layer, an n-type charge generation layer and a p-type charge generation layer formed in this order between the different adjacent stacks, and a second electrode formed on an n^{th} stack, wherein the p-type charge generation layer includes an indenofluorenedione derivative of Formula 1 or an imine derivative of Formula 2 or 3, wherein details of Formulae 1, 2 and 3 are defined as above.

It is to be understood that both the foregoing general description and the following detailed description of the present application are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention.

FIG. 1 is a sectional view illustrating an organic light emitting device according to the present application.

FIGS. 2A to 2D are sectional views illustrating the region S of FIG. 1 of Reference Examples 1 and 2 and first and second embodiments according to the present application.

FIGS. 3A to 3D illustrate energy band gaps of the respective layers shown in FIGS. 2A to 2D.

FIG. 4 is a graph showing JV properties of devices A and D and Reference Examples 1 and 2.

FIG. 5 is a graph showing spectra of devices A to D and Reference Examples 1 and 2.

FIG. 6 is a graph showing EQE of the devices A to D and Reference Example 1 and 2 as a function of luminance.

FIG. 7 is a graph showing a variation in luminance with time and an increase in driving voltage with time, of the devices A to D and Reference Examples 1 and 2.

FIG. 8 is a sectional view illustrating an organic light emitting display device using the organic light emitting device according to the present application.

### DETAILED DESCRIPTION OF THE INVENTION

Reference will now be made in detail to the preferred embodiments of the present application, examples of which are illustrated in the accompanying drawings. Wherever possible, the same reference numbers will be used throughout the drawings to refer to the same or like parts.

Hereinafter, a white organic light emitting device according to the present application will be described in detail with reference to the annexed drawings.

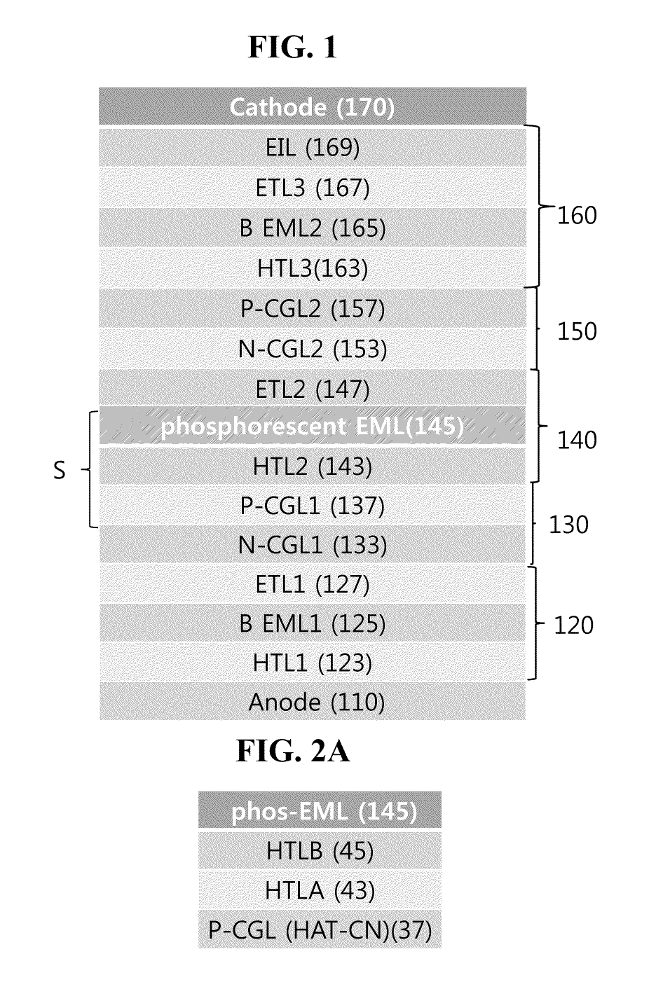

FIG. 1 is a sectional view illustrating an organic light emitting device according to the present application.

As shown in FIG. 1, the organic light emitting device according to the present application has n (wherein n is a natural number of 2 or more) stacks 120, 140 and 160 interposed between an anode 110 and a cathode 170. Although only three stacks are described in the drawing, the present application is not limited thereto and two stacks or four or more stacks may be applied.

As shown in FIG. 1, when the organic light emitting device includes a first blue stack 120, a phosphorescent stack 140 and a second blue stack 160 disposed in this order from the bottom as the respective stacks, the organic light emitting device may be implemented as a white organic light emitting device. For example, a light emitting layer 145 of the phosphorescent stack 140 (hereinafter, referred to as a “phosphorescent emitting layer” 145) emits yellow green or yellowish green light or red green light. As shown in the drawing, the phosphorescent emitting layer 145 is for example a yellowish green light emitting layer.

Here, the phosphorescent emitting layer 145 of the phosphorescent stack 140 includes a host of at least one hole transport material and a host of at least one electron transport material and includes a dopant emitting light of a wavelength of a yellow green or yellowish green region, or red green region.

The phosphorescent stack includes at least one phosphorescent stack in three or more stacks and enables implementation of a full-white panel with a high-luminance of 200 nit or more. In this case, when the yellowish green phosphorescent emitting layer is used, a luminescence peak wavelength is 540 to 580 nm and preferably, a maximum luminescence peak is 550 to 570 nm. In this case, a half-width is 80 nm or more.

In addition, one or two dopants may be contained in the phosphorescent emitting layer of the phosphorescent stack. When two dopants are present, the dopants may be doped at different concentrations. In this case, the respective dopants are not doped to thicknesses not more than 400 Å.

Meanwhile, the first and second blue stacks 120 and 160 include blue fluorescent emitting layers 125 and 165, respectively. In some cases, if development of materials is possible, the blue fluorescent emitting layers may be changed to blue phosphorescent emitting layers.

In addition, the respective stacks of the organic light emitting device according to the present application include hole transport layers 123, 143 and 163, light emitting layers 125, 145 and 165, and electron transport layers 127, 147 and 167 disposed in this order. Here, a triplet level of each of the hole transport layers 123, 143 and 163, and electron transport layers 127, 147 and 167 adjacent to the light emitting layers 125, 145 and 165 of the respective stacks 120, 140 and 160 are preferably 0.01 eV to 0.4 eV higher than a triplet level of a host of the light emitting layers 125, 145 and 165. This serves to prevent excitons generated in the respective light emitting layers from moving to the hole transport layer or the electron transport layer adjacent to the corresponding light emitting layer so that the generated excitons are confined in the respective layers, respectively.

Meanwhile, the organic light emitting device may further include a hole injection layer between the anode 110 and the hole transport layer 123 of the first blue stack 120.

In addition, the organic light emitting device may further include an electron injection layer 169 between the second blue stack 160 and the cathode 170 as shown in the drawing. The electron injection layer 169 may be omitted if necessary.

In addition, the organic light emitting device may further include n-type charge generation layers 133 and 153 and p-type charge generation layers 137 and 157 respectively provided between different adjacent stacks, and the p-type charge generation layers 137 and 157 comprise an indenofluorenedione derivative represented by the following Formula 1, or an imine derivative represented by Formula 2 or 3.

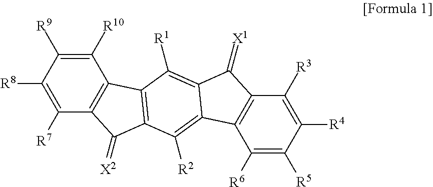

wherein X¹ and X² each independently represents any one of Formulae (I) to (V), R¹ to R¹⁰ each independently represents a hydrogen atom, an alkyl group, an aryl group, a heterocycle, a halogen atom, a fluoroalkyl group, an alkoxy group, an aryloxy group or a cyano group, and R³ to R⁶ or R⁷ to R¹⁰ are bonded to one another to form a ring.

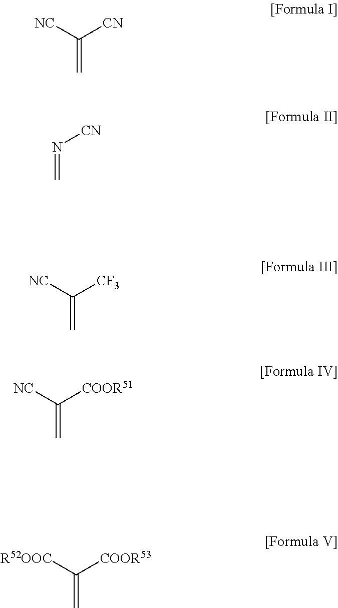

In addition, in Formulae IV to V, R⁵¹ to R⁵³ each independently represents a hydrogen atom, a fluoroalkyl group, an alkyl group, an aryl group or a heterocycle, and R⁵² and R⁵³ are bonded to each other to form a ring.

In the formulae, X¹ and X² are identical or different and R1 to R10 are also identical or different.

Alternatively, the p-type charge generation layers 137 and 157 may comprise a compound represented by the following Formula 2 or 3.

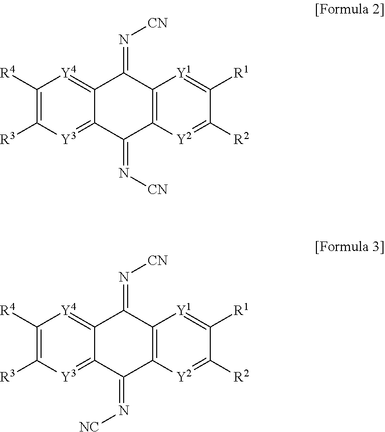

In Formula 2 or 3, Y¹ to Y⁴ each independently represents a carbon or nitrogen atom, R¹ to R⁴ each independently represents a hydrogen atom, an alkyl group, an aryl group, a heterocycle, a halogen atom, a fluoroalkyl group or a cyano group, and R¹ and R², or R³ and R⁴ are each bonded together to form a ring.

In addition, the p-type charge generation layers 137 and 157 including the compound of any one of Formulae 1 to 3 may have a thickness of 50 Å to 200 Å.

In addition, the hole transport layers 143 and 163 most adjacent to the p-type charge generation layers 137 and 157, respectively, may have a thickness of 50 Å to 700 Å. In this case, the hole transport layers 143 and 163 include a hole transport material capable of blocking injection of electrons or excitons generated in an adjacent light emitting layer.

In addition, the hole transport layers 143 and 163 most adjacent to the p-type charge generation layers 137 and 157 may have a triplet level of 2.5 eV or more and for example has a monolayer structure composed of a single material. For example, the material for the hole transport layers 143 and 163 is m-MTDATA, but the present application is not limited thereto.

In addition, the hole transport layer 123 adjacent to the cathode may include a first layer composed of a general hole transport material such as NPD and a second layer having relatively low HOMO composed of a material such as m-MTDATA.

Meanwhile, the reason for using the indenofluorenedione derivative of Formula 1 or the imine derivative of Formula 2 or 3 as a major component in the p-type charge generation layers 137 and 157 of the organic light emitting device according to the present application is that the adjacent hole transport layer is formed as a monolayer and holes generated by charge separation are more easily transported to the hole transport layers 143 and 163.

A material commonly used for the p-type hole transport layer is HAT-CN. Use of this material alone enables formation of the p-type hole transport layer. However, HAT-CN disadvantageously requires formation of a double hole transport layer between the p-type hole transport layer and the light emitting layer. Accordingly, in the present application, the p-type hole transport layer is formed as a single layer by using the compound of Formula 1 or 3 as a single material or by doping a portion of components of the hole transport layer which is a monolayer of the adjacent stack so that an energy barrier is reduced during injection of holes and driving voltage is thus reduced. In case of the latter method, each energy difference of HOMO levels of the hole transport layers 143 and 163 from LUMO levels of most adjacent to the p-type charge generation layers 137 and 157 is preferably lower than or equal to 0.3 eV. That is, an energy value subtracting of each HOMO level of the hole transport layers 143 and 163 from each LUMO level of the host of the adjacent p-type charge generation layer is in a range of −0.3 eV to +0.3 eV. In this case, the p-type charge generation layers 137 and 157 include the indenofluorenedione derivative of Formula 1 or the imine derivative of Formula 2 or 3 as a host and a component of the hole transport layers 143 and 163 most adjacent to the p-type charge generation layers as a dopant. In addition, the component of the hole transport layers is preferably present in an amount of 0.5% to 10% in the p-type charge generation layers 137 and 157.

Here, the p-type charge generation layer including the component of one of Formulae 1 to 3 according to the present application as a major component in an amount of at least 90% may be applied between all stacks provided in the organic light emitting device and between some stacks.

Meanwhile, the n-type charge generation layers 133 and 153 include an organic substance having an electron transport property and an n-type organic dopant. Alternatively, the n-type charge generation layers 133 and 153 include an organic substance having an electron transport property and a metal selected from an alkali metal group (1A) and an alkaline earth metal group (2A) as a dopant. The dopant is for example generally a metal such as Li. The organic or metal dopant may be contained in an amount of 0.4% to 3% in the n-type charge generation layer.

In addition, the organic substance having an electron transport property constituting the n-type charge generation layers 133 and 153 may have a fused aromatic ring including a heterocyclic ring.

The n-type charge generation layers 133 and 153 may have a thickness of 50 Å to 250 Å.

Meanwhile, according to light emission direction, the anode 110 or the cathode 170 may contact a substrate (not shown). In addition, a plurality of pixels forming a matrix is defined in the substrate, a thin film transistor is formed in each pixel and the thin film transistor is connected to the anode 110 or the cathode 170.

Specifically, energy levels of the p-type charge generation layer/hole transport layer according to the present application and p-type charge generation layer/hole transport layer according to Reference Examples compared with the present application will be described with reference to the following drawings.

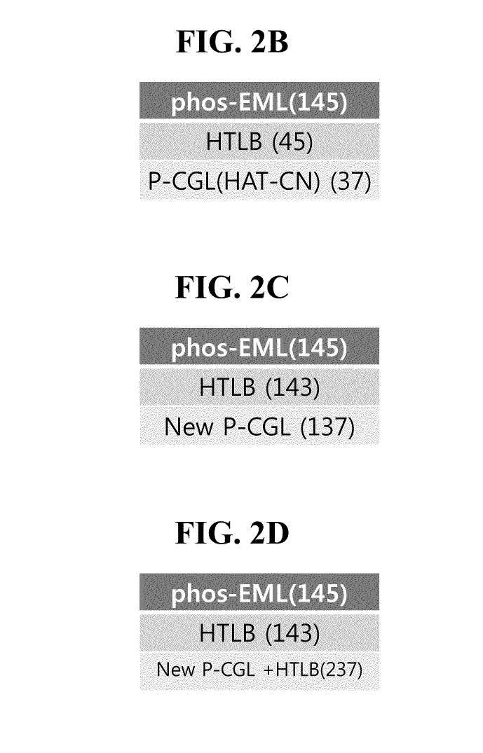

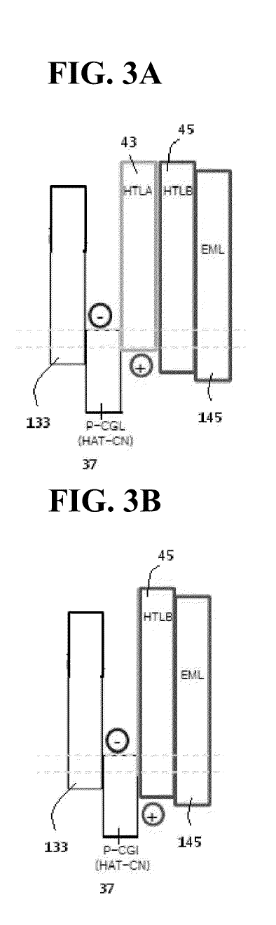

FIGS. 2A to 2D are sectional views illustrating the region S of FIG. 1 of Reference Examples 1 and 2 and first and second embodiments according to the present application, and FIGS. 3A to 3D illustrate energy band gaps of the respective layers shown in FIGS. 2A to 2D.

FIGS. 2A and 3A illustrate Reference Example 1. The region S of FIG. 1 includes a p-type charge generation layer composed of a single material of HATCN (Formula 4), a first hole transport layer 43 (HTLA) and a second hole transport layer 45.

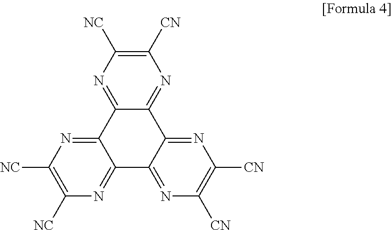 [SMILES: N#Cc1nc2c3nc(C#N)c(C#N)nc3c3nc(C#N)c(C#N)nc3c2nc1C#N]

Both the first hole transport layer (HTLA) 43 and the second hole transport layer (HTLB) 45 are hole transporting organic substances, but the second hole transport layer (HTLB) 45 is adjacent to the light emitting layer 145 and function as electron or exciton-blocking layers capable of confining excitons generated in the light emitting layer 145 or electrons present therein, in the light emitting layer 145. In addition, a HOMO energy level of the second hole transport layer 45 has a lower than that of the first hole transport layer 43.

The reason for using two hole transport layers in Reference Example 1 is that the first hole transport layer 43 (HTLA) effectively improves injection of holes from the p-type charge generation layer 37 and controls cavity. In addition, the second hole transport layer (HTLB) 45 functions to block electrons for improvement of efficiency in the phosphorescent stack and to prevent triplet diffusion. These functions of the second hole transport layer 45 are due to that the second hole transport layer 45 has a triplet energy level that is 0.01 eV to 0.4 eV higher than that of the adjacent light emitting layer 145.

FIGS. 2B and 3B illustrate Reference Example 2. The region S of FIG. 1 includes a p-type charge generation layer 137 composed of a single material of HATCN (Formula 4) and a hole transport layer 45 of a single layer. In the following comparative experiment, the hole transport layer 45 having the single layer is formed using the same material as the second hole transport layer (HTLB) of the Reference Example 1.

In addition, FIGS. 2C and 3C illustrate a first embodiment of the present application. The region S of FIG. 1 includes a p-type charge generation layer 137 composed of a single material selected from Formulae 1 to 3 and a hole transport layer 143 having a single layer. In the following comparison experiment, the hole transport layer 143 of the single layer is formed using the same material as the second hole transport layer (HTLB) of Reference Example 1.

Here, the number of layers decreases as compared to Reference Example 2 because the hole transport layer 143 is formed as a single layer. An adjacent hole transport layer 143 is formed using a hole transport material capable of blocking electrons or excitons to obtain similar effects to Reference Example 1 including a hole transport layer having a double layer structure, and p-type charge generation layers are formed using a material having lower LUMO than HAT-CN used for Reference Example to further reduce an energy barrier during charge separation and to facilitate transport of holes to an adjacent stack from the p-type charge generation layer 137.

In addition, FIGS. 2D and 3D illustrate a second embodiment of the present application. The region S of FIG. 1 includes a p-type charge generation layer 237 using a single material selected from Formulae 1 to 3 as a host and using a component of an adjacent hole transport layer 143 as a dopant, and a hole transport layer 143 as a single layer. In the following comparison experiment, the hole transport layer 143 of the single layer is formed using the same material as the second hole transport layer (HTLB) of Reference Example 1.

In the first and second embodiments according to the present application, the organic substances of Formulae 1 to 3 used in common for the p-type charge generation layers 137 and 237 have a LUMO 0.1 eV to 0.2 eV lower than that of HAT-CN used in Reference Examples 1 and 2. That is, transport of holes to the adjacent hole transport layer 143 is easy.

In addition, in the first and second embodiments according to the present application, a HOMO level of the hole transport layer 143 most adjacent to the p-type charge generation layers 137 and 237 is lower than or equal to a value obtained by adding 0.3 eV to a LUMO level of the host of the adjacent p-type charge generation layer. And the HOMO level of the hole transport layer 143 most adjacent to the p-type charge generation layers 137 and 237 is higher than or equal to a value obtained by subtracting 0.3 eV from the a LUMO level of the host of the adjacent p-type charge generation layer. Materials of the p-type charge generation layers 137 and 237 and the hole transport layer 143 are selected in consideration of LUMO and HOMO levels.

In the second embodiment, the reason for doping the p-type charge generation layer 237 with the component of the hole transport layer 143 is as follows. As described in the first embodiment, partial accumulation of holes at the interface between the p-type charge generation layer 137 and the hole transport layer 143 may interrupt effective charge separation. To solve this problem, the p-type charge generation layer is doped with a small amount of material for the hole transport layer to partially reduce a barrier gap at the interface between the p-type charge generation layer and the hole transport layer and to cause effective charge separation. This provides the effects of reducing driving voltage and increasing lifespan.

The component of the hole transport layer contained in the p-type charge generation layer may change from 0.5% to 10%. From results of the experiments, driving voltage is highest at a doping concentration of about 3%. When the concentration of the component of the hole transport layer contained in the p-type charge generation layer is about 0.5% to about 3%, driving voltage decreases. In a concentration range of 3% to 10%, the driving voltage increases. In this regard, the reason for setting the doping concentration of the component of the hole transport layer to 0.5% to 10% is that, within this range, a superior driving voltage property (low driving voltage) is obtained as compared to Reference Example 2.

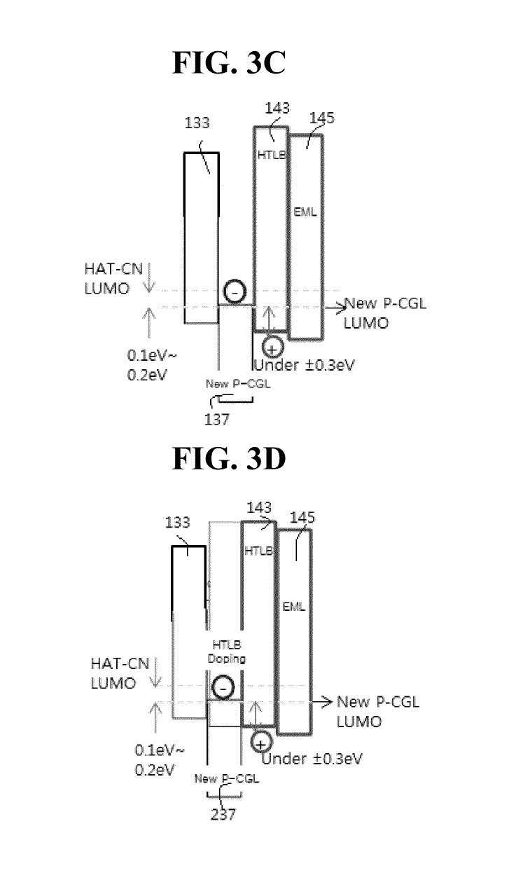

The following Table 1 and the graphs shown in FIGS. 4 to 7 show experiments on Reference Examples 1 and 2 described above and a device A according to the first embodiment of the present application and devices B to D having different doping concentrations according to the second embodiment of the present application and a detailed explanation thereof is given below.

Respective layers are formed using the following materials in the experiments. In the respective experiments, the material for the region S of FIG. 1 (p-type charge generation layer and hole transport layer adjacent thereto) is changed and the materials for other layers are the same in Reference Examples 1 and 2 and the devices A to D. In the following experiments, the component used for HTLA is N,N′-Di-[(1-naphthyl)-N,N′-diphenyl]-1,1′-biphenyl)-4,4′-diamine) and the component used for HTLB is m-MTDATA (4,4′,4″-Tris(N-3-methylphenyl-N-phenylamino)triphenylamine) represented by Formula 5.

Meanwhile, in devices A to D and Reference Example 2, in the phosphorescent stack 140 and the second blue stack 160 respectively including hole transport layers 143 and 163 respectively adjacent to the p-type charge generation layers, the hole transport layers 143 and 163 are formed as a single layer in the corresponding stack using m-MTDATA (4,4′,4″-Tris(N-3-methylphenyl-N-phenylamino)triphenylamine) as the material for the hole transport layers 143 and 163. On the other hand, in Reference Example 1, the hole transport layers of the phosphorescent stack and the second blue stack are formed to have a double layer structure including HTLA (NPD) and HTLB (m-MTDATA) as described above.

In addition, in all of the devices A to D, Reference Example 2, and Reference Example 1, the hole transport layer 123 of the first blue stack 120 adjacent to the anode is formed to have a double layer structure including HTLA (NPD) and HTLB (m-MTDATA).

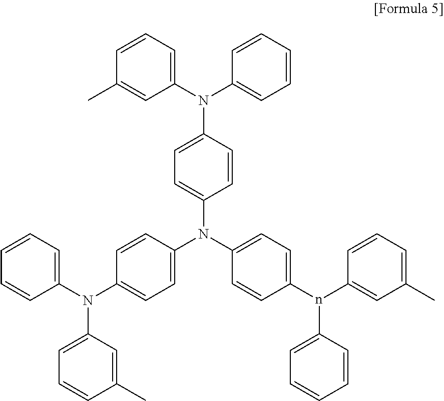

As can be seen from the values shown in Table 1 and the graphs, when a major component for the p-type charge generation layer is the indenofluorenedione derivative of Formula 1 and when the major component is the imine derivative of Formula 2 or 3, driving voltage, efficiency, EQE properties and lifespan are substantially similar. Thus, Table 1 and the graphs are shown without distinction of Formulae 1, 2 and 3.

Meanwhile, indium tin oxide (ITO) is used as the anode and aluminum (Al) or an aluminum alloy is used as the cathode.

In addition, NPD (N,N′-Di-[(1-naphthyl)-N,N′-diphenyl]-1,1′-biphenyl)-4,4′-diamine) is used as the hole transport layer adjacent to the anode in the first blue stack.

ADN (9,10-Di(2-naphthyl)anthracene) is used as a host of the blue light emitting layer and BCzSB (1,4-bis(4-(9H-carbazol-9-yl)styryl)benzene) is used as a host of the blue light emitting layer.

TPBi (1,3,5-Tri(1-phenyl-1Hbenzo[d]imidazol-2-yl)phenyl) or HNBphen(2-(naphthalen-2-yl)-4,7-diphenyl-1,10-phenanthroline) is used as a material for the electron transport layer.

NBphen (2,9-bis(naphthalen-2-yl)-4,7-diphenyl-1,10-phenanthroline) is used as a host of the n-type charge generation layers and Li or Ca is used as an n-type dopant. In the Reference Example of the experiment, the same dopant, Li, is doped.

BCBP (2,2′-bis(4-(carbazol-9-yl)phenyl)-biphenyl) is used as a host of the light emitting layer of the phosphorescent stack and fac-Bis(2-(3-p-xylyl)phenyl)pyridine-2-phenylqunoline Iridium (III) is used as a dopant thereof.

The electron injection layer adjacent to the cathode of the second blue stack is formed using LiF.

TABLE 1

| | | Ref 1 | Ref 2 | A | B | C | D |
|---|---|---|---|---|---|---|---|
| Phosphorescent | | HTLA/ | HTLB | HTLB | | | |
| and second blue | | HTLB | | | | | |
| stacks | | | | | | | |
| P-CGL material | | HAT-CN | | Derivatives of Formulae 1 to 3 | | | |
| P-CGL thickness | | P-CGL: 100 Å | | P-CGL | P-CGL: | P-CGL: | P-CGL: |
| and HTLB | | | | 100Å | 100 Å | 100 Å | 100 Å |
| concentration | | | | | HTLB: | HTLB: | HTLB: |
| | | | | | +3% | +5% | +10% |
| @50 | Voltage | 14.5 | 19.5 | 14.5 | 14.1 | 14.3 | 14.9 |
| mA/cm2 | (A) | | | | | | |
| @10 | | 11.9 | 15.8 | 11.8 | 11.6 | 11.7 | 12.1 |
| mA/cm2 | Efficacy | 86.3 | 72.9 | 86.6 | 86.5 | 86.9 | 87.4 |
| | (cd/A) | | | | | | |
| | EQE | 35.3 | 32.6 | 35.2 | 35.2 | 35.6 | 35.7 |
| | (%) | | | | | | |

As can be seen from Table 1 above, the respective p-type charge generation layers in the experiments are formed to have a thickness of 100 Å and a single component of HAT-CN is used for Reference Examples 1 and 2, a single component of any one of Formulae 1 to 3 is used for the device A, any one component of Formulae 1 to 3 is used for a host of devices B to D and a component for an adjacent single hole transport layer, HTLB, is doped at different concentrations of 3%, 5% and 10%.

In particular, it should be noted that there is significant difference in driving voltage, efficiency and external quantum efficiency between Reference Example 1 wherein the hole transport layer has a double layer structure of HTLA/HTLB and Reference Example 2 wherein the hole transport layer has a single layer of HTLB.

That is, the material for the hole transport layer in Reference Example 2 is the same as that of the present application and Reference Example 2 is only different from the present application in that HAT-CN alone is used as the material for the p-type charge generation layer. The driving voltage of Reference Example 2 is 4.6 V higher than those of devices A to D of the present application at a current density of 50 mA/cm² and the driving voltage of Reference Example 2 is 3.7 V higher than those of the devices A to D of the present application at a current density of 10 mA/cm², thus having an about 31% or higher required driving voltage.

In addition, comparing efficacy properties (experiments at current density of 10 mA/cm²), Reference Example 2 exhibits an efficacy of 72.9 cd/A, and devices A to D exhibit an efficacy of at least 86.5 cd/A. This indicates that the present application exhibits an increase in efficacy of at least 19%.

In addition, in terms of external quantum efficiency (EQE) (experiments at a current density of 10 mA/cm²), Reference Example 2 exhibits an EQE of 32.6% and the devices A to D exhibit an EQE of at least 35.2%. This indicates that the present application exhibits an increase in EQE of at least about 8%.

Meanwhile, Reference Example 1 exhibits a similar driving voltage to the devices A to D, but the hole transport layer should be formed as a double layer structure. In this case, materials and process times are increased, the number of interfaces increases and defects to the interfaces thus more readily occur upon practical application of the devices. Accordingly, a direct comparison between Reference Example 1 and the devices A to D is omitted.

FIG. 4 is a graph showing JV properties of devices A and D and Reference Examples 1 and 2.

As shown in FIG. 4, directly comparing a correlation of current density with respect to driving voltage between Reference Examples 1 and 2 and the devices A to D, the driving voltage at a constant current density decreases in order of device B, device C, device A, Reference Example 1, device D and Reference Example 2. That is, when a concentration of the component of the hole transport layer in the p-type charge generation layers is 3% and a major component thereof is the indenofluorenedione derivative of Formula 1 or the imine derivative of Formula 2 or 3, the driving voltage is found to be lowest at a constant current density. That is, an amount of the hole transport layer doped in the p-type charge generation layer is small, i.e., 10% or less.

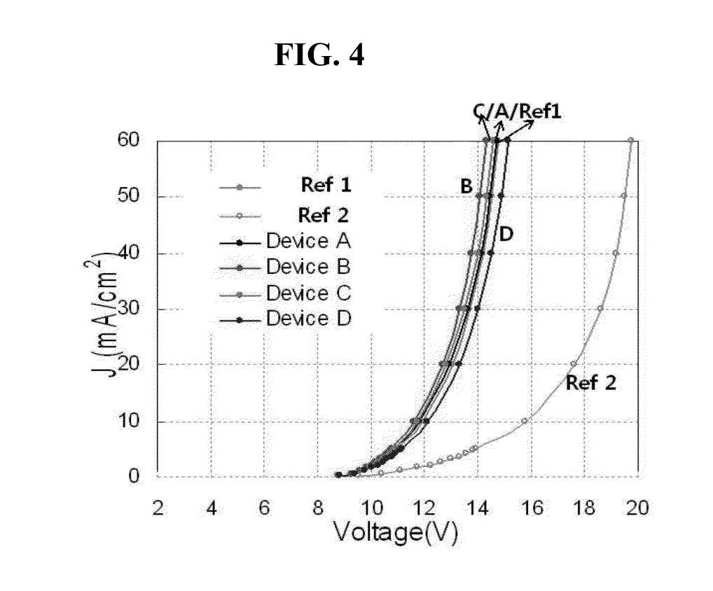

FIG. 5 is a graph showing spectra for devices A to D and Reference Examples 1 and 2.

As shown in FIG. 5, spectrum properties showing intensities of the devices A to D and Reference Example 1 at different wavelengths are substantially similar. That is, maximum luminescence intensities are observed in blue and yellow green regions. Reference Example 2 also exhibits similar behaviors, but has relatively low efficiency of the phosphorescent stack. For this reason, the luminescence intensity of the yellow green light emitting layer of the phosphorescent stack is lower than those of Reference Example 1 and the devices A to D.

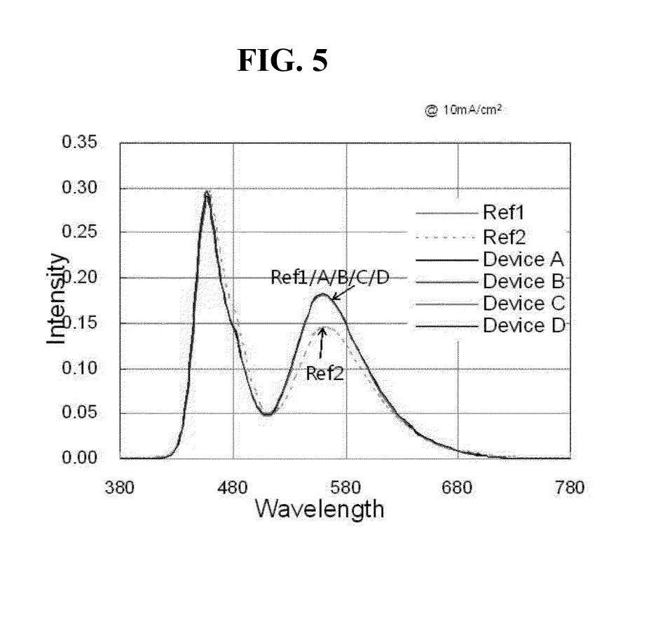

FIG. 6 is a graph showing EQE according luminance of the devices A to D and Reference Examples 1 and 2.

As shown in FIG. 6, regarding external quantum efficiency according to luminance, Reference Examples 1 and 2 exhibit similar behaviors to the devices A to D. Reference Example 2 exhibits maximum quantum efficiency at initial luminance and then shows a significant difference of about 5% or more from other examples. The reason for this is that a barrier between the p-type charge generation layer and the hole transport layer is high.

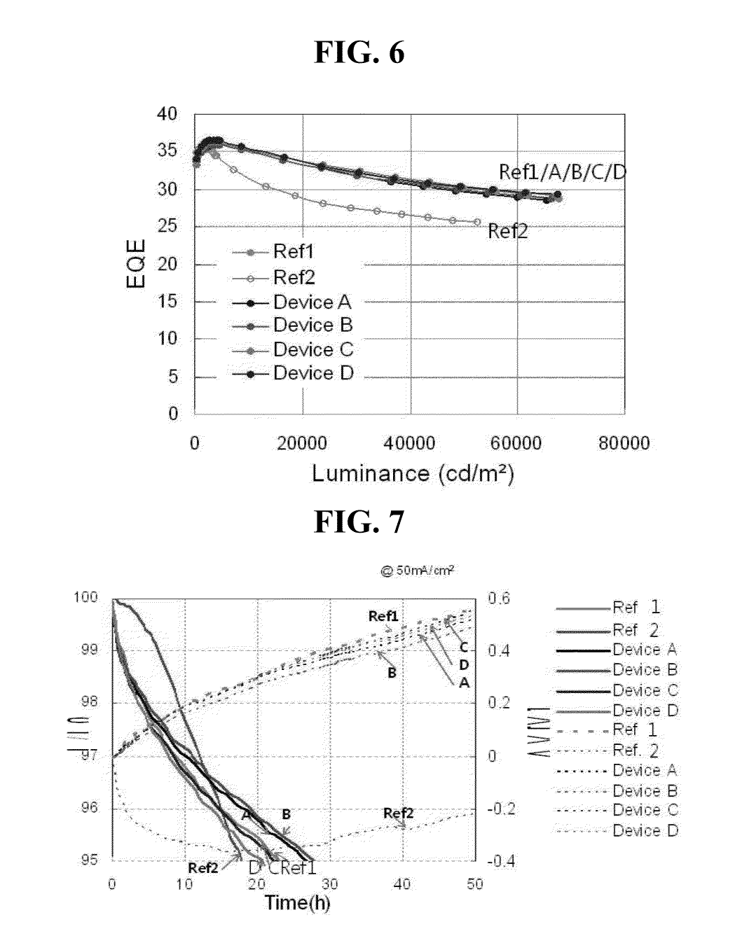

FIG. 7 is a graph showing a variation in luminance with time and an increase in driving voltage with time, of the devices A to D and Reference Examples 1 and 2.

As can be seen from FIG. 7, upon observing while a variation in luminance as compared to initial luminance (L0) (L/L0) with time is changed from about 100% to about 95% at a current density 50 mA/cm², Reference Example 2 exhibits a lifespan shorter than 20 hours, unlike other examples.

The device B exhibits the longest lifespan among the other examples and lifespan decreases in order of the device A, Reference Example 1, the device C and the device D.

In addition, as compared to the devices B and A exhibiting similar levels of about 28 hours, Reference Example 1 exhibits a lifespan of about 23 hours. The present application exhibits a 20% increase in lifespan as compared to Reference Example 1, by controlling a doping amount to an optimal level, or forming a p-type charge generation layer of a single layer using a material selected from Formulae 1 to 3.

In addition, regarding variation in driving voltage (ΔV) with time, Reference Example 1 exhibits the highest ΔV of about 0.58V and ΔV decreases in order of the devices C, D, A and B. The most superior device B exhibits the lowest ΔV of about 0.49V. In this case, reliability is considered to increase due to low variation in driving voltage with time.

Meanwhile, Reference Example 2 exhibits a low ΔV of a negative value, but has a poor lifespan property. Accordingly, it is difficult to select Reference Example 2 based on only ΔV and comparison therewith is omitted.

The organic light emitting device according to the present application has a structure enabling simplification of the hole transport layer by using the indenofluorenedione derivative of Formula 1 or the imine derivative of Formula 2 or 3 for the material for the p-type charge generation layer and enables decreases in voltage and ΔV through effective stabilization of barrier gap between LUMO of the p-type charge generation layer and HOMO of the hole transport layer adjacent thereto by doping the p-type charge generation layer with a small amount of the component of the hole transport layer most adjacent to the p-type charge generation layer.

In conventional cases, regarding a charge generation layer structure of a stack-type devices, performance is superior when applying various materials of p-type charge generation layers to an n-type charge generation layer formed by doping an electron transport material with an alkali metal, in particular, when forming p-type charge generation layers using HAT-CN as a material, but in this case, problems of driving voltage or lifespan remain unsolved.

The organic light emitting device according to the present application relates to improvement in driving voltage through layer simplification. This case exhibits equivalent or high efficacies, excellent lifespan properties and improved progressive driving voltage, as compared to a case in which a hole transport layer having a double layer structure is used, based on simplification of the hole transport layer through change of the p-type charge generation layer structure.

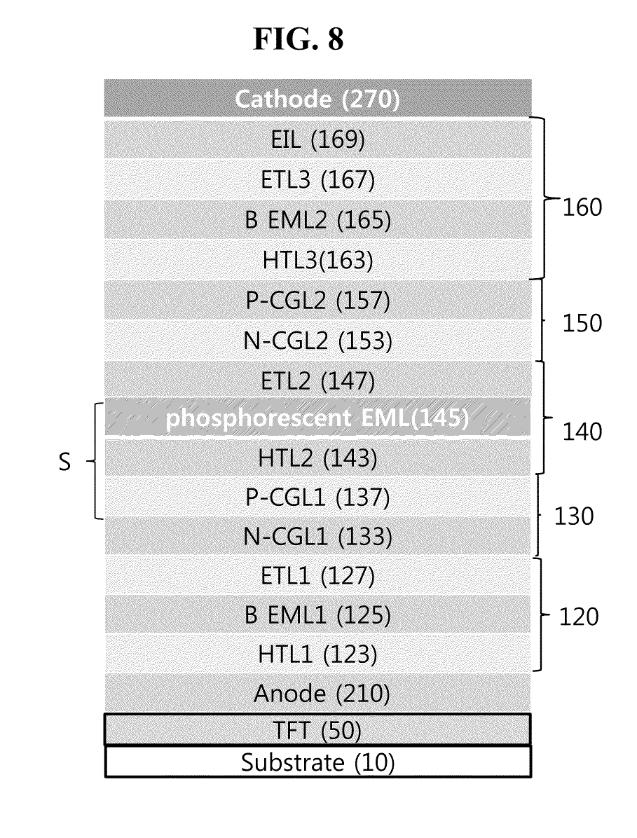

FIG. 8 is a sectional view illustrating an organic light emitting display device using the organic light emitting device according to the present application.

FIG. 8 illustrates an example of the organic light emitting display device which includes a substrate 10 having a plurality of pixels defined in the form of a matrix, a thin film transistor 50 provided in each pixel, a first electrode 210 connected to the thin film transistor 50, and a second electrode 270 facing the first electrode 210, and includes a first blue stack 120, a first charge generation layer 130, a phosphorescent stack 140, a second charge generation layer 150 and a second blue stack 160 disposed in this order between the anode 210 and the cathode 270.

The first blue stack 120, the first charge generation layer 130, the phosphorescent stack 140, the second charge generation layer 150 and the second blue stack 160 have been described with reference to FIG. 1 above.

Such an organic light emitting display device displays white organic light emission and respective stacks and charge generation layers are formed over the entire surface of the active region of the substrate and color filters are used for rendering color on a pixel basis.

In addition, when the organic light emitting display device according to the present application has a thickness of at least 2,500 Å to 5,000 Å from the first electrode to the second electrode and the phosphorescent stack has a light emitting layer of yellow green or double light emitting layers of yellow green and green to secure viewing angle and red efficiency, the distance from the cathode to the yellow green light emitting layer and the adjacent hole transport layer is formed to a thickness of at least 2,000 Å.

In addition, the effects of improving efficiency and reducing driving voltage can be obtained by doping a small amount of a single component of any one derivative of Formulae 1 to 3, or a component of the hole transport layer most adjacent thereto, as a material for the p-type charge generation layers, in order to reduce the number of layers.

The organic light emitting device according to the present application and the organic light emitting display device using the same have the following effects.

In a structure including a plurality of light emitting units, a single layer composed of an indenofluorenedione derivative or an imine derivative having a lower LUMO than a conventional material composed of a single material is formed as a p-type hole transport layer adjacent to the hole transport layer of the units, among charge generation layers provided between the units. As a result, similar efficiency and low driving voltage, as compared to a structure further including an electron- or exciton-blocking layer in addition to the hole transport layer adjacent to a conventional p-type hole transport layer composed of a single material can be obtained, although a hole transport layer having a single layer is provided between the light emitting layer of the adjacent stack and the charge generation layer.

In a structure including a plurality of light emitting units, only a hole transport layer having a single layer between the light emitting layer and the charge generation layer of adjacent stacks is formed by using an indenofluorenedione derivative or an imine derivative having a lower LUMO than a conventional material composed of a single material, as a host for a p-type hole transport layer adjacent to the hole transport layer of each of the units, among charge generation layers provided between the units, and doping the p-type hole transport layer with a small amount of the component of the hole transport layer most adjacent thereto. As a result, it is advantageously possible to simplify the overall layer structure and to obtain superior efficiency, low driving voltage and progressive driving voltage (ΔV) and improved lifespan, as compared to a structure further including an electron- or exciton-blocking layer in addition to the hole transport layer adjacent to a conventional p-type hole transport layer composed of a single material, although a hole transport layer having a single layer structure is provided between the light emitting layer of the adjacent stack and the charge generation layer.

It will be apparent to those skilled in the art that various modifications and variations can be made in the present application without departing from the spirit or scope of the inventions. Thus, it is intended that the present application covers the modifications and variations of this invention provided they come within the scope of the appended claims and their equivalents.

What is claimed is:

1. An organic light emitting device comprising n stacks between an anode and a cathode,
wherein n is 2 or more,
wherein the stacks comprise a hole transport layer, a light emitting layer and an electron transport layer,
wherein an n-type charge generation layer and a p-type charge generation layer are provided between the different adjacent stacks,
wherein the p-type charge generation layer comprises an indenofluorenedione derivative represented by Formula 1 or an imine derivative represented by Formula 2 or 3: 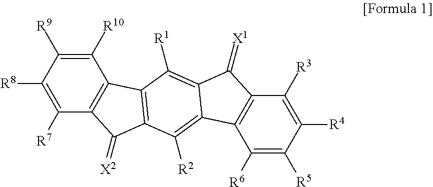
wherein in Formula (1), X¹ and X² each independently represents any one of Formulae (I) to (V), R¹ to R¹⁰ each independently represents a hydrogen atom, an alkyl group, an aryl group, a heterocycle, a halogen atom, a fluoroalkyl group, an alkoxy group, an aryloxy group or a cyano group, and R³ to R⁶ or R⁷ to R¹⁰ are bonded to each other to form a ring, 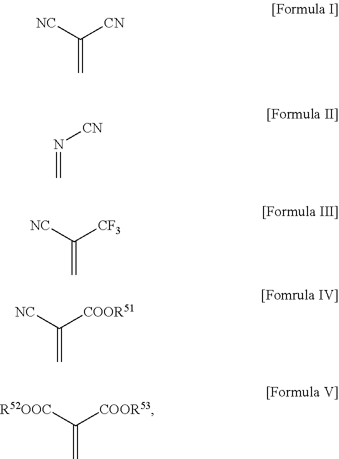
wherein R⁵¹ to R⁵³ each independently represents a hydrogen atom, a fluoroalkyl group, an alkyl group, an aryl group or a heterocycle, and R⁵² and R⁵³ are bonded to each other to form a ring; 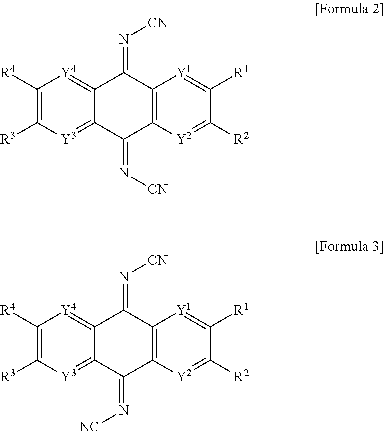
wherein in Formulae 2 and 3, Y¹ to Y⁴ each independently represents a carbon or nitrogen atom, R¹ to R⁴ each independently represents a hydrogen atom, an alkyl group, an aryl group, a heterocycle, a halogen atom, a fluoroalkyl group or a cyano group, and R¹ and R², or R³ and R⁴ are bonded to each other to form a ring.

2. The organic light emitting device according to claim 1, wherein the p-type charge generation layer further comprises a component of the hole transport layer most adjacent to the p-type charge generation layer as a dopant.

3. The organic light emitting device according to claim 2, wherein the component of the hole transport layer is present in an amount of 0.5% to 10% in the p-type charge generation layer.

4. The organic light emitting device according to claim 1, wherein the p-type charge generation layer has a thickness of 50 Å to 200 Å.

5. The organic light emitting device according to claim 1, wherein the thickness of the hole transport layer most adjacent to the p-type charge generation layer is 50 Å to 700 Å.

6. The organic light emitting device according to claim 1, wherein the hole transport layer most adjacent to the p-type charge generation layer has a triplet level of 2.5 eV or more.

7. The organic light emitting device according to claim 1, wherein a difference between a LUMO level of the p-type charge generation layer and a HOMO level of the hole transport layer most adjacent to the p-type charge generation layer is smaller than or equal to 0.3 eV.

8. The organic light emitting device according to claim 3, wherein the n stacks present between the anode and the cathode comprise three stacks,
a light emitting layer of a first stack adjacent to the anode and a light emitting layer of a third stack adjacent to the cathode are blue light emitting layers, and
a light emitting layer of a second stack is a phosphorescent emitting layer and emits yellow green or yellowish green light, or red green light.

9. The organic light emitting device according to claim 8, wherein the phosphorescent emitting layer of the second stack comprises a host of at least one hole transport material and a host of at least one electron transport material.

10. The organic light emitting device according to claim 1, wherein the n-type charge generation layer comprises an electron-transporting organic substance and an n-type organic dopant.

11. The organic light emitting device according to claim 1, wherein the n-type charge generation layer comprises an electron-transporting organic substance as a host and a metal selected from the group consisting of an alkali metal and an alkaline earth metal as a dopant.

12. The organic light emitting device according to claim 11, wherein the electron-transporting organic substance constituting the n-type charge generation layer is a fused aromatic ring including a heterocyclic ring.

13. The organic light emitting device according to claim 11, wherein the dopant is present in an amount of 0.4% to 3% in the n-type charge generation layer.

14. The organic light emitting device according to claim 1, wherein the n-type charge generation layer has a thickness of 50 Å to 250 Å.

15. The organic light emitting device according to claim 1, wherein a triplet level of the hole transport layer and the electron transport layer adjacent to the light emitting layer of each stack is 0.01 eV to 0.4 eV higher than a triplet level of a host of the light emitting layer.

16. An organic light emitting display device comprising:
a substrate having a plurality of pixels defined in the form of a matrix, the substrate including a thin film transistor disposed in each of the pixels;
a first electrode connected to the thin film transistor;
n stacks disposed on the first electrode, the stacks each comprising a hole transport layer, a light emitting layer and an electron transport layer, wherein n is 2 or more;
an n-type charge generation layer and a p-type charge generation layer formed in this order between the different adjacent stacks; and
a second electrode formed on an n^{th} stack,
wherein the p-type charge generation layer comprises an indenofluorenedione derivative of Formula 1 or an imine derivative of Formula 2 or 3,
wherein X¹ and X² each independently represents any one of Formulae (I) to (V), R¹ to R¹⁰ each independently represents a hydrogen atom, an alkyl group, an aryl group, a heterocycle, a halogen atom, a fluoroalkyl group, an alkoxy group, an aryloxy group or a cyano group, and R³ to R⁶ or R⁷ to R¹⁰ are bonded to each other to form a ring, 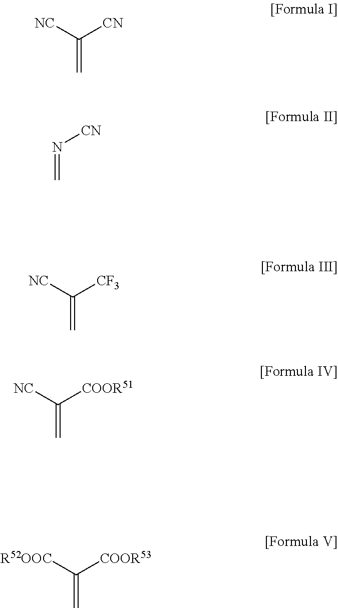
wherein R⁵¹ to R⁵³ each independently represents a hydrogen atom, a fluoroalkyl group, an alkyl group, an aryl group or a heterocycle, and R⁵² and R⁵³ are bonded to each other to form a ring, 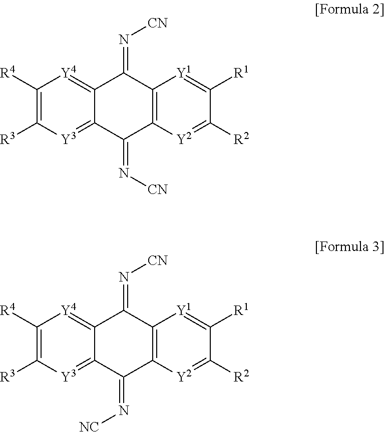
wherein in Formulae 2 and 3, Y¹ to Y⁴ each independently represents a carbon or nitrogen atom, R¹ to R⁴ each independently represents a hydrogen atom, an alkyl group, an aryl group, a heterocycle, a halogen atom, a fluoroalkyl group or a cyano group, and R¹ and R², or R³ and R⁴ are bonded to each other to form a ring.

17. The organic light emitting display device according to claim 16, wherein the p-type charge generation layer further comprises a component of the hole transport layer most adjacent to the p-type charge generation layer as a dopant.

18. The organic light emitting display device according to claim 17, wherein the component of the hole transport layer is present in an amount of 0.5% to 10% in the p-type charge generation layer.
